(19) United States
(12) Patent Application Publication
(10) Pub. No.: US 2011/0103419 A1
(43) Pub. Date: May 5, 2011

(54) OPTICAL DEVICE

(75) Inventors: Rintaro Koda, Tokyo (JP); Takao Miyajima, Kanagawa (JP); Hideki Watanabe, Kanagawa (JP); Hiroyuki Yokoyama, Miyagi (JP); Tomoyuki Oki, Kanagawa (JP); Masaru Kuramoto, Kanagawa (JP)

(73) Assignees: TOHOKU UNIVERSITY, Miyagi (JP); Sony Corporation, Tokyo (JP)

(21) Appl. No.: 12/910,046

(22) Filed: Oct. 22, 2010

(30) Foreign Application Priority Data
Oct. 30, 2009 (JP) 2009-250624
Mar. 2, 2010 (JP) 2010-045394

(51) Int. Cl. H01S 5/00; H01S 3/02; H01S 3/08

(52) U.S. Cl. 372/45.01; 359/333; 359/344; 359/346

(57) ABSTRACT

The present invention provides an optical device capable of suppressing a drive current and an optical output to be varied with a passage of the time. The optical device includes: an optical element including a first end face and a second end face, and emitting light having a wavelength from 300 nm to 600 nm both inclusive at least from the second end face in the first end face and the second end face; a pedestal including a supporting substrate supporting the optical element, and a connecting terminal electrically connected to the optical element; and a sealing section including a light transmitting window in each of a portion facing the first end face and a portion facing the second end face, and sealing the optical element.

### BACKGROUND OF THE INVENTION

1. Field of the Invention

The present invention relates to an optical device which incorporates an optical element (for example, a semiconductor laser or an optical amplifying element).

2. Description of the Related Art

From the past, in the field of a semiconductor laser, a solid laser represented by a titanium-sapphire laser has been mainly used in a short wavelength. However, since the solid laser is expensive and large, the semiconductor laser which is inexpensive and small has been expected to come into practical use in substitution for the solid laser. If the semiconductor laser having the short wavelength is put into practical use, the semiconductor laser may be used as a light source of a volume type optical disk which corresponds to a next-generation high density optical disk (blu-ray disk). Further, by using the semiconductor laser together with a semiconductor laser having another wavelength band, a convenient light source covering the entire wavelength band of a visible light range may be realized, and it may be possible to provide various light sources demanded in the field of medical care, bioimaging, and the like.

However, in the semiconductor laser having the short wavelength, it is not easy to obtain a high output as in the solid laser. Thus, to obtain the high output, for example, it is considered to use an optical amplifying element, and use an external resonator (for example, refer to Japanese Unexamined Patent Publication No. 2001-015833).

### SUMMARY OF THE INVENTION

However, when the output of the semiconductor laser having the short wavelength is increased, there is an issue that a drive current and an optical output are varied with the passage of time.

In view of the foregoing, it is desirable to provide an optical device capable of suppressing a drive current and an optical output from being varied with a passage of time.

According to an embodiment of the present invention, there is provided an optical device including: an optical element; and a pedestal including a supporting substrate supporting the optical element, and a connecting terminal electrically connected to the optical element. The optical element includes a first end face and a second end face, and emits light having a wavelength of 430 nm or less at least from the second end face in the first end face and the second end face. Further, the optical device includes a sealing section including a light transmitting window in each of a portion facing the first end face and a portion facing the second end face, and sealing the optical element.

In the optical device according to the embodiment of the present invention, the optical element is sealed by the sealing section, and the light transmitting window is provided in each of the portion facing the first end face and the portion facing the second end face in the sealing section. Therefore, it may be possible to seal the optical element without inhibiting light irradiation to the optical element, and light emission from the optical element.

Here, in the optical device according to the embodiment of the present invention, the optical element may serve an optical amplifying element amplifying the light incident into the first end face, and emitting the light having a luminance larger than that of the incident light at least from the second end face in the first end face and the second end face. Further, the optical element may be configured as a semiconductor laser. However, in the case where the optical element is configured as the semiconductor laser, a third lens in a region facing the light transmitting window on the second end face side in the two light transmitting windows, and a reflecting mirror are preferably provided in this order from the light transmitting window side. Further, the second end face includes an antireflection film on the surface, and the first end face preferably includes a second reflection coating film having a reflectance of a degree that an external resonator is configured by the first end face and the reflecting mirror in the light having the wavelength of 430 nm or less.

According to the optical device of the embodiment of the present invention, it may be possible to seal the optical element without inhibiting the light irradiation to the optical element and the light emission from the optical element. Therefore, it may be possible to suppress a slight amount of a Si organic gas contained in an external atmosphere from being reacted with the laser light to generate a deposited material on the first end face and the second end face. As a result, it may be possible to suppress a drive current and an optical output from being varied with a passage of time.

Other and further objects, features and advantages of the invention will appear more fully from the following description.

### BRIEF DESCRIPTION OF THE DRAWINGS

FIG. 1 is a cross-sectional view of an optical amplifying device in the longitudinal direction, according to a first embodiment of the present invention.

FIG. 2 is a cross-sectional view of the optical amplifying device of FIG. 1 in the transverse direction.

FIGS. 3A and 3B are cross-sectional views illustrating an example of an optical amplifying element of FIG. 1.

FIG. 4 is a cross-sectional view illustrating another example of the optical amplifying element of FIG. 1.

FIG. 5 is a cross-sectional view illustrating still another example of the optical amplifying element of FIG. 1.

FIG. 6 is a schematic view illustrating the state in which the optical amplifying device of FIG. 1 is installed on an optical path of a light emitting device.

FIG. 7 is a characteristic view illustrating variation of luminance deterioration caused by the passage of time in the case where the optical amplifying element is sealed, and in the case where the optical amplifying element is not sealed.

FIG. 8 is cross-sectional view illustrating a modification of the optical amplifying device of FIG. 1.

FIG. 9 is a cross-sectional view illustrating another modification of the optical amplifying device of FIG. 1.

FIG. 10 is a cross-sectional view of the light emitting device in the longitudinal direction, according to a second embodiment of the present invention.

FIG. 11 is a schematic view illustrating the state where an external resonator is set in the light emitting device of FIG. 10.

FIGS. 12A and 12B are optical output spectrum views of the optical amplifying device according to an example.

FIG. 13 is a relationship view between an output power and an input power of the optical amplifying device according to the example.

### DETAILED DESCRIPTION OF THE PREFERRED EMBODIMENTS

Hereinafter, embodiments of the present invention will be described in detail with reference to the drawings. The description will be made in the following order.

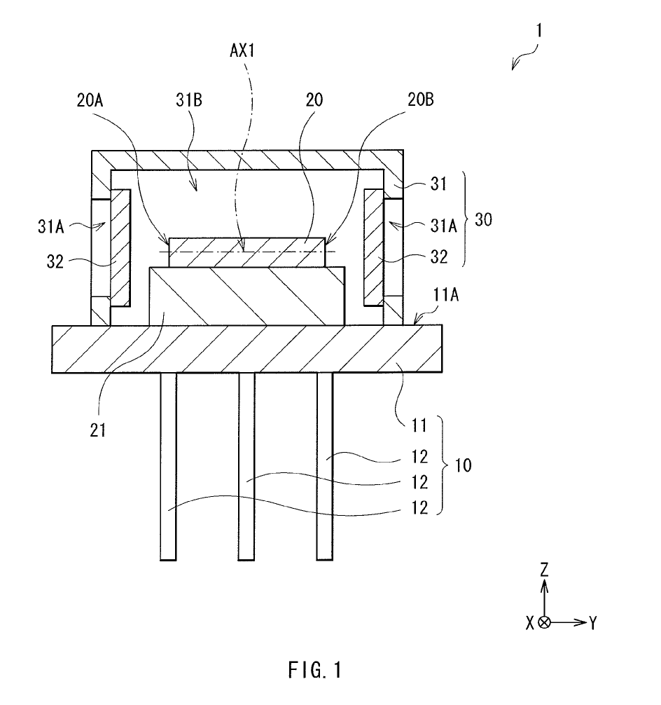

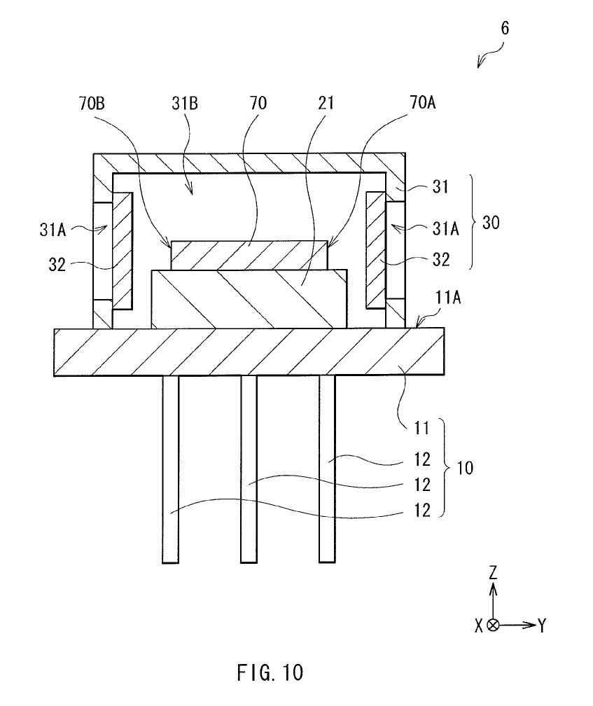

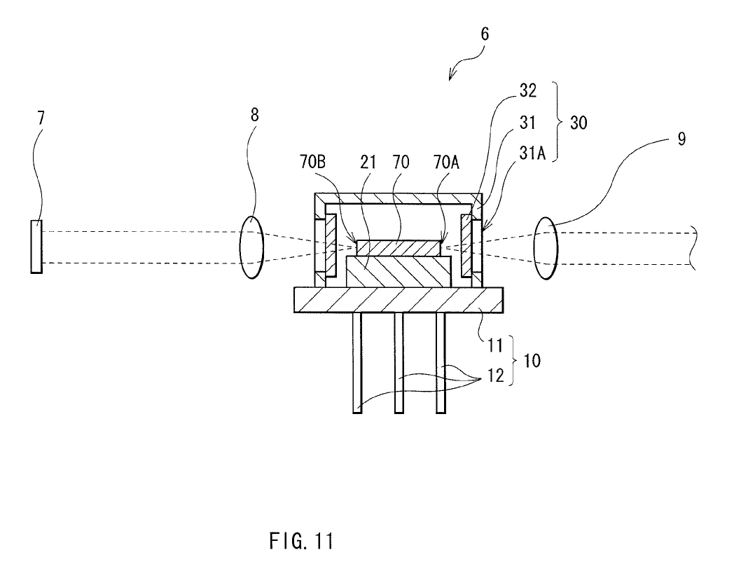

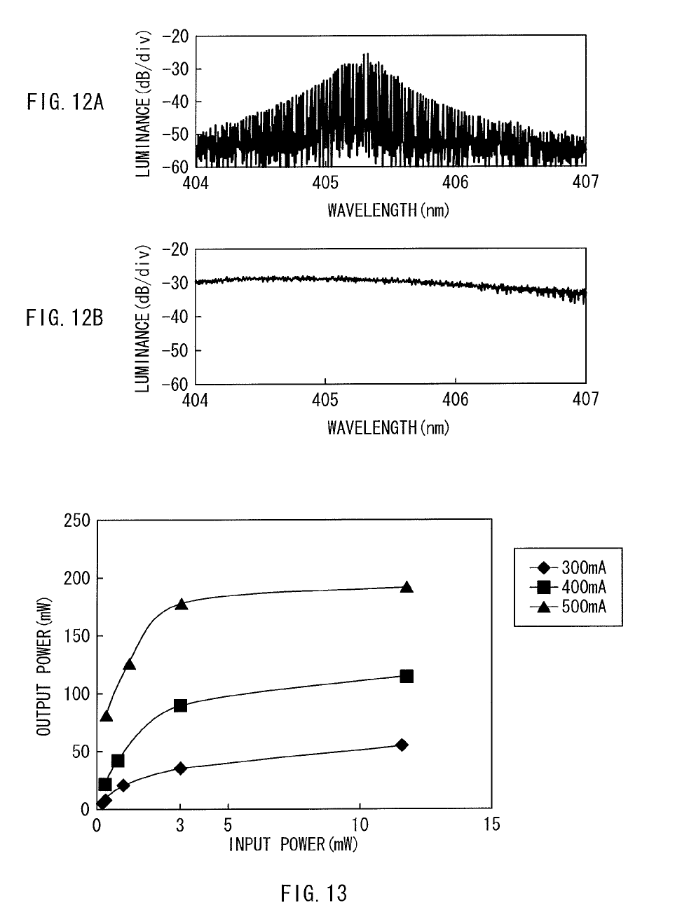

1. First embodiment (optical amplifying device, FIGS. 1 to 2, 3A, 3B, 4 to 9)
2. Second embodiment (light emitting device, FIGS. 10 and 11)
3. Example (optical amplifying device, FIGS. 12A, 12B, and 13)

### 1. First Embodiment

### Structure of an Optical Amplifying Device 1

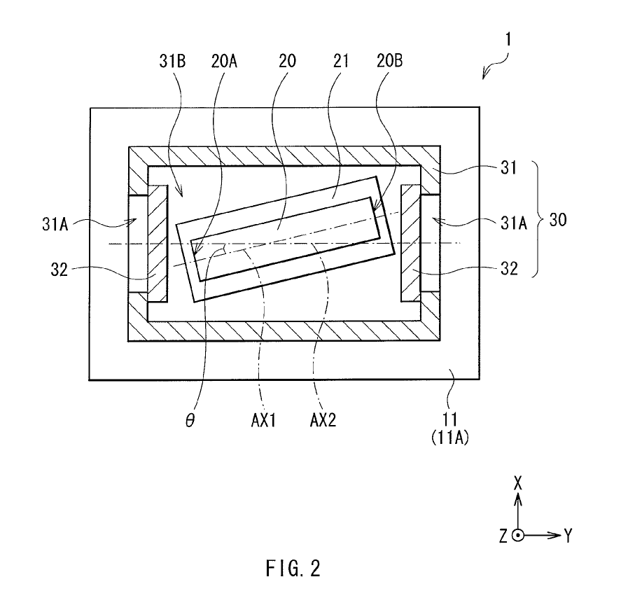

FIG. 1 illustrates an example of the cross-sectional structure of an optical amplifying device 1 in the longitudinal direction, according to a first embodiment of the present invention. FIG. 2 illustrates an example of the cross-sectional structure of the optical amplifying device 1 of FIG. 1 in the transverse direction. In addition, FIGS. 1 and 2 are schematic illustrations, and the dimensions and the shapes are different from actual dimensions and actual shapes.

The optical amplifying device 1 of this embodiment includes, for example, a stem 10, an optical amplifying element 20, and a cap 30. The stem 10 corresponds to a specific example of “pedestal” of the present invention. The optical amplifying element 20 corresponds to a specific example of “optical element” of the present invention. The cap 30 corresponds to a specific example of “sealing section” of the present invention.

The stem 10 constitutes a package of the optical amplifying device 1 in corporation with the cap 30, and includes, for example, a supporting substrate 11 supporting the optical amplifying element 20, and a plurality of connecting terminals 12. The supporting substrate 11 has, for example, a square shape as illustrated in FIG. 2, and a top face 11A of the supporting substrate 11 has such a size that the cap 30 may be placed (fixed) on the top face 11A. The plurality of connecting terminals 12 penetrate the supporting substrate 11, for example, are projected long on the opposite side from the top face 11A, and are projected short on the top face 11A side. In the plurality of connecting terminals 12, a portion projected long on the opposite side from the top face 11A corresponds to a portion fitted into a substrate for a light source or the like. Meanwhile, in the plurality of connecting terminals 12, a portion projected short on the top face 11A side corresponds to a portion electrically connected to the optical amplifying element 20 through wiring (not illustrated in the figure) or the like. The plurality of connecting terminals 12 are supported by an insulating member (not illustrated in the figure) provided in the supporting substrate 11. The plurality of connecting terminals 12 and the supporting substrate 11 are insulated and separated from each other by the above-described insulating member. Further, the individual connecting terminals 12 are also insulated and separated from each other by the above-described insulating member.

The optical amplifying element 20 is mounted on the top face 11A of the supporting substrate 11. For example, in the state of being arranged on a sub-mount 21, the optical amplifying element 20 is mounted on the top face 11A. Although not illustrated in the figure, the optical amplifying element 20 may be in direct contact with the supporting substrate 11. The optical amplifying element 20 is generally referred to as a transmissive SOA (semiconductor optical amplifier). This optical amplifying element 20 includes an incidence-side end face 20A (first end face) and an emission-side end face 20B (second end face), and emits light from the emission-side end face 20B in the incidence-side end face 20A and the emission-side end face 20B. The center wavelength (wavelength λ1) of the light (stimulated emission light) emitted from the optical amplifying element 20 is, for example, from 300 nm to 600 nm both inclusive, preferably from 360 nm to 550 nm both inclusive, and more preferably from 360 nm to 430 nm both inclusive. Further, the optical amplifying element 20 amplifies the light incident into the incidence-side end face 20A, and emits the light having a luminance larger than that of the incident light from the emission-side end face 20B.

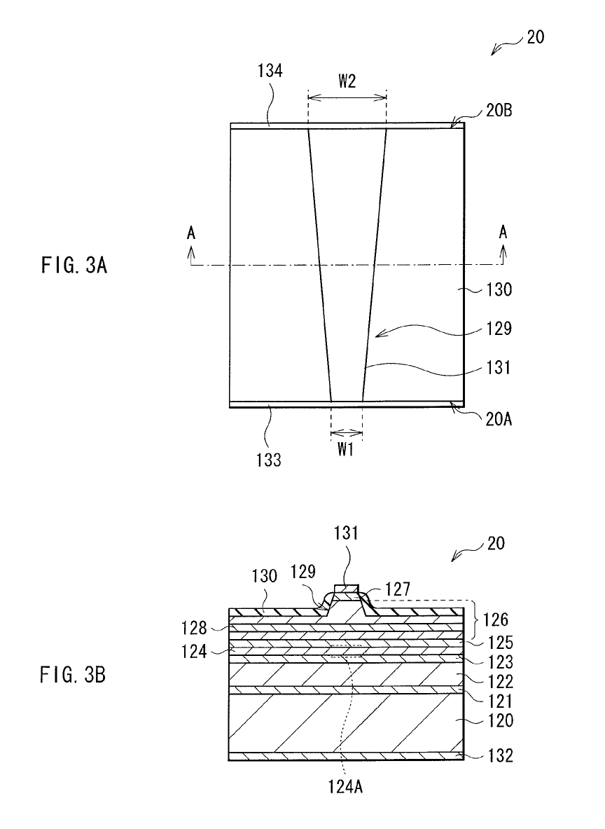

As illustrated in FIGS. 3A and 3B, for example, the optical amplifying element 20 includes semiconductor layers which include a buffer layer 121, a lower cladding layer 122, a lower guiding layer 123, an active layer 124, an upper guiding layer 125, an upper cladding layer 126, and a contact layer 127 on a substrate 120 in this order from the substrate 120 side. Further, the optical amplifying element 20 includes, for example, an electron barrier layer 128 in the upper cladding layer 126. In addition, in the optical amplifying element 20, layers other than the above-described layers may be further provided, and a part of the above-described layers (for example, the buffer layer 21, the electron barrier layer 128, or the like) may be omitted.

The substrate 120 is made of, for example, a group III-V nitride semiconductor having the wurtzite crystal structure, such as GaN. Here, “group III-V nitride semiconductor” denotes a semiconductor containing at least one kind selected from group 3B elements in the short form periodic table, and at least N selected from group 5B elements in the short form periodic table. Examples of the group III-V nitride semiconductor include a gallium nitride compound containing Ga and N. Examples of the gallium nitride compound include GaN, AlGaN, AlGaInN. The group III-V nitride semiconductor is doped with an n-type impurity such as Si, O, C, Ge, Zn, and Cd, or a p-type impurity such as Mg, and Zn, if necessary.

Like the substrate 120, the semiconductor layers on the substrate 120 contain, for example, the group III-V nitride semiconductor (for example, AlGaInN). The buffer layer 121 is composed of, for example, an n-type GaN. The lower cladding layer 122 is composed of, for example, an n-type AlGaN. The lower guiding layer 123 is composed of, for example, non-doped GaInN. The active layer 124 is composed of, for example, a multiquantum well obtained by alternately stacking a well layer and a barrier layer which are formed of GaInN having composition ratios different from each other, respectively. The barrier layer of the active layer 124 is, for example, doped with the n-type impurity of approximately 1×10¹⁶ cm⁻³ to 5×10¹⁹ cm⁻³. In this case, by the barrier layer of the active layer 124, it may be possible to suppress the Quantum Stark effect by piezoelectricity, which is applied to the quantum well.

The upper guiding layer 125 is composed of, for example, non-doped GaInN. In the upper cladding layer 126, the layer on the active layer 124 side is composed of, for example, the non-doped GaInN in relation to the electron barrier layer 128. Meanwhile, in the upper guiding layer 125, the layer on the contact layer 127 side is composed of, for example, an Mg doped GaN/AlGaN superlattice in relation to the electron barrier layer 128. The contact layer 127 is composed of, for example, Mg doped GaN. The electron barrier layer 128 is composed of, for example, Mg doped AlGaN.

Here, the lower guiding layer 123 and the upper guiding layer 125 may have a thickness larger than a thickness generally applied in a low-output type semiconductor layer for communication, or the like. In this case, since the light confinement in the stacking direction (vertical direction) is slightly weak, a beam radiation half-value angle θ⊥ in the vertical direction is large (for example, 25 degrees or less). Depending on the degree of the light confinement in the vertical direction, there is a case where the transverse mode in the vertical direction becomes a secondary or higher order mode. However, even in that case, in this embodiment, the light is sufficiently confined at least by a ridge 129 in the transverse mode in the transverse direction, and the transverse mode is a single mode.

In the upper part of the semiconductor layers on the substrate 120, specifically, in the upper part of the upper cladding layer 126 and the contact layer 127, the strip-shaped ridge 129 is formed. The ridge 129 constitutes an optical waveguide in corporation with portions located on both ends of the ridge 129 in the semiconductor layers on the substrate 120, performs the light confinement in the transverse direction by utilizing the refractive index difference in the transverse direction (direction orthogonal to the resonator direction), and constricts a current injected into the semiconductor layers on the substrate 120. In the active layer 124, a portion immediately below the above-described optical waveguide corresponds to a current injecting region, and this current injecting region serves as a light emitting region 124A.

On the surfaces of both side faces of the ridge 129, and on the surface of the vicinity of the ridge 129, an insulating film 130 is formed. The insulating film 130 is made of an insulating material such as an oxide and a nitride, and is configured, for example, by stacking SiO₂ and Si in this order from the upper cladding layer 126 side. The insulating film 130 basically protects the optical amplifying element 20, but a function to suppress the high order mode is given to the insulating film 130, if necessary. Here, in the case where a material of the insulating film 130 is selected so that an effective refractive index difference Δn in the transverse direction is, for example, from 5×10⁻³ to 1×10⁻² both inclusive, it can be said that the insulating film 130 has the function to suppress the high order mode.

When viewing the ridge 129 from the stacking direction of the semiconductor layers, the ridge 129 is in a linear shape. The ridge 129 extends, for example, in the direction parallel to an “m” axis or a “c” axis (not illustrated in the figure) of the wurtzite crystal structure. In addition, the ridge 129 may, for example, extend in the direction intersecting the “m” axis or the “c” axis of the wurtzite crystal structure at an angle within a range of more than 0 degree and equal to or less than 45 degrees. In that case, the ridge 129 preferably extends in the direction intersecting the “m” axis or the “c” axis of the wurtzite crystal structure at an angle within a range of more than 0 degree and equal to or less than 10 degrees.

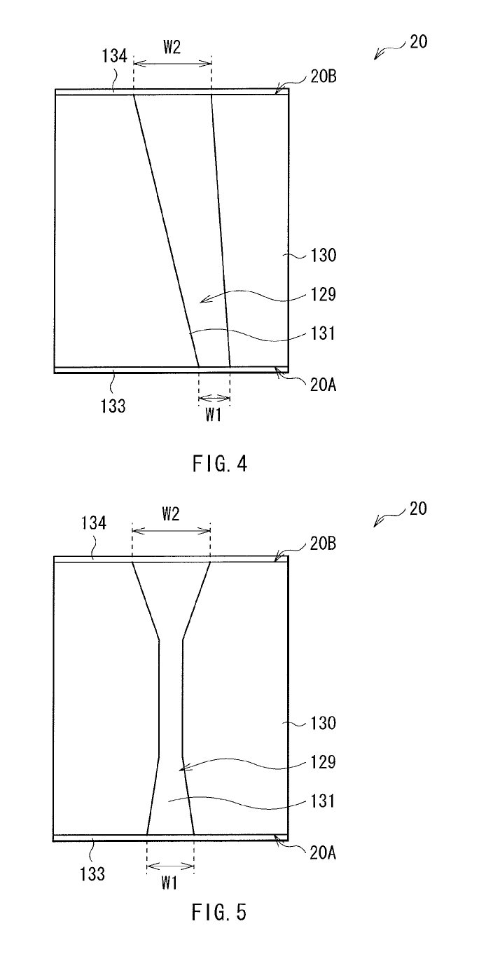

The length (device length) of the ridge 129 is, for example, within a range from 300 μm to 10 nm both inclusive, and is, for example, 3 mm. For example, as illustrated in FIG. 3A, the width of the ridge 129 is narrow in the vicinity of the incidence-side end face 20A, and becomes wide from the incidence-side end face 20A toward the emission-side end face 20B. In other words, in this case, the ridge 129 has a so-called flare structure. In addition, the ridge 129 may not extend in the direction orthogonal to the incidence-side end face 20A and the emission-side end face 20B, for example, as illustrated in FIG. 3A, and the ridge 129 may extend in the direction obliquely intersecting the incidence-side end face 20A and the emission-side end face 20B, for example, as illustrated in FIG. 4. For example, as illustrated in FIG. 5, the width of the ridge 129 may be narrow in the middle section in the longitudinal direction (resonator direction), and may be wide in the vicinity of the end faces of both the incidence-side end face 20A and the emission-side end face 20B, in comparison with the middle section.

A width W1 of the ridge 129 on the incidence-side end face 20A side is smaller than a width W2 of the ridge 129 on the emission-side end face 20B side. For example, the width W1 is 2 μm or less. For example, when the device length is 3 mm, the width W1 is approximately 1.4 μm. For example, the width W2 is 1000 μm or less, and preferably 10 μm or less. For example, when the device length is 3 mm, the width W2 is approximately 5 μm.

In the semiconductor layers on the substrate 120, the pair of the incidence-side end face 20A and the emission-side end face 20B sandwiching the ridge 129 from the extending direction of the ridge 129 are formed. The incidence-side end face 20A and the emission-side end face 20B are formed by cutting a wafer (not illustrated in the figure) in a manufacturing process, and are, for example, cleaved faces formed by cleavage. The resonator is composed of the incidence-side end face 20A and the emission-side end face 20B in the stacked plane direction.

The incidence-side end face 20A is a face into which the light output from a light emitting device 2 which will be described later is incident, and an antireflection film 133 is formed on the surface of the incidence-side end face 20A. Meanwhile, the emission-side end face 20B is a face from which the laser light is emitted, and an antireflection film 134 is formed on the surface of the emission-side end face 20B. The antireflection films 133 and 134 are configured by stacking one or a plurality of films made of the oxide or the nitride. The antireflection films 133 and 134 have, for example, a one-layer structure of Al₂O₃, SiO₂, MN, or the like. Alternatively, the antireflection films 133 and 134 have, for example, a two-layer structure of TiO₂/Al₂O₃, ZrO₂/SiO₂, Ta₂O₃/SiO₂, or the like. Therefore, when the light output from the light emitting device 2 which will be described later, and the light output from the optical amplifying element 20 are vertically incident into the antireflection films 133 and 134, the antireflection films 133 and 134 transmit the light at a reflectance of, for example, 10⁻³ (0.1%) or less.

On the top face (surface of the contact layer 127) of the ridge 129, an upper electrode 131 is provided. The upper electrode 131 is, for example, configured by stacking Ti, Pt, and Au in this order, and is electrically connected to the contact layer 127. Meanwhile, on the rear surface of the substrate 120, a lower electrode 132 is provided. The lower electrode 132 is, for example, configured by stacking an alloy of Au and Ge, Ni, and Au in this order from the substrate 120 side, and is electrically connected to the substrate 120.

The surface of the contact layer 127 as being the top face of the optical amplifying element 20, and the rear surface of the substrate 120 as being the bottom face of the optical amplifying element 20 are, for example, “c” planes of the wurtzite crystal structure, and the incidence-side end face 20A and the emission-side end face 20B are “m” planes of the wurtzite crystal structure at this time. Further, the top face and the bottom face of the optical amplifying element 20 are, for example, the “m” planes or the “c” planes of the wurtzite crystal structure, and the incidence-side end face 20A and the emission-side end face 20B are the “c” planes of the wurtzite crystal structure at this time.

Here, in the case where the incidence-side end face 20A and the emission-side end face 20B are the “m” planes of the wurtzite crystal structure, when the ridge 129 extends in the direction intersecting the “m” axis of the wurtzite crystal structure, the ridge 129 extends in the direction obliquely intersecting the incidence-side end face 20A and the emission-side end face 20B, for example, as illustrated in FIG. 4. In the same manner, in the case where the incidence-side end face 20A and the emission-side end face 20B are the “c” planes of the wurtzite crystal structure, when the ridge 129 extends in the direction intersecting the “c” axis of the wurtzite crystal structure, the ridge 129 extends in the direction obliquely intersecting the incidence-side end face 20A and the emission-side end face 20B, for example, as illustrated in FIG. 4.

The optical amplifying element 20 is arranged in such a manner that an optical axis AX1 parallel to a normal of the incidence-side end face 20A and the emission-side end face 20B becomes parallel to the top face 11A, and the optical amplifying element 20 outputs the light in the direction parallel to the top face 11A. As illustrated in FIG. 2, the optical amplifying element 20 is preferably arranged in such a manner that the optical axis AX1 intersects a normal AX2 of a light transmitting window 32 which will be described later at an angle θ (0°<θ≦45°). In other words, the optical amplifying element 20 is preferably arranged in such a manner that the incidence-side end face 20A is directed in the direction that the incidence-side end face 20A and the light transmitting window 32 do not frontally face each other. This is because a phenomenon that the light incident into the incidence-side end face 20A returns to the light source which is not illustrated in the figure, that is, generation of so-called returning light may be eliminated. However, in the case where generation of the returning light is not an issue, although not illustrated in the figure, the optical amplifying element 20 may be arranged in such a manner that the optical axis AX1 is parallel to the normal AX2.

The cap 30 seals the optical amplifying element 20. The cap 30 includes a tube 31 in which an aperture 31A is provided in each of a portion facing the incidence-side end face 20A, and a portion facing the emission side end face 20B. The lower end of the tube 31 is fixed onto the top face 11A, and the optical amplifying element 20 is positioned in an internal space 31B of the tube 31. The internal space 31B is filled with, for example, a Si organic compound gas having an extremely-low vapor pressure.

The cap 30 includes the light transmitting windows 32 arranged so as to close the two apertures 31A provided on the side faces of the tube 31. For example, as illustrated in FIGS. 1 and 2, the light transmitting windows 32 are arranged in the internal space 31B of the tube 31, and have a function to transmit the light incident into the incidence-side end face 20A of the optical amplifying element 20, and the light output from the emission-side end face 20B of the optical amplifying element 20. For example, although not illustrated, on the surface, the light transmitting windows 32 contain a transparent member in which antireflection films having the same function as the antireflection films 133 and 134 which are formed in the optical amplifying element 20 are formed.

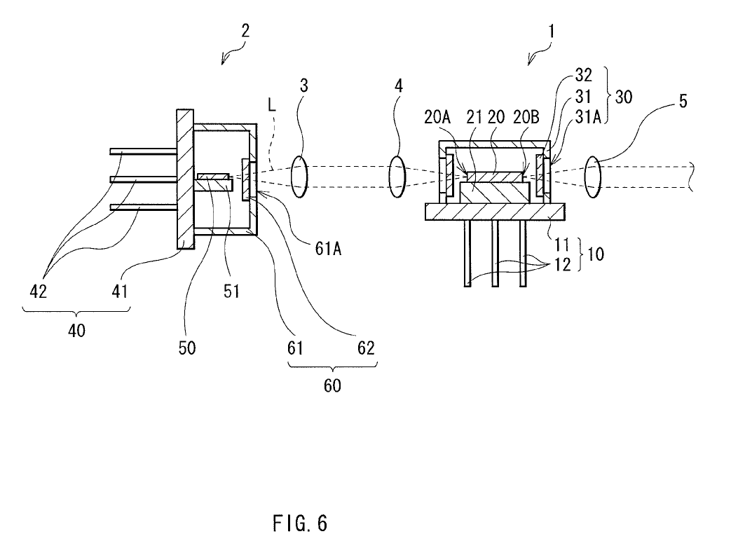

For example, as illustrated in FIG. 6, the optical amplifying device 1 of this embodiment is arranged on the optical axis of light L having a short wavelength (430 nm or less) output from the light emitting device 2. Specifically, the two light transmitting windows 32 provided in the cap 30 are arranged on the optical axis of the light emitting device 2, and the light transmitting window 32 on the incidence-side end face 20A side of the optical amplifying element 20 in the two light transmitting windows 32 is directed toward the light emitting device 2 side. Further, the optical amplifying device 1 is arranged in such a manner that the normal AX2 (not illustrated in FIG. 6) of the light transmitting window 32 on the incidence-side end face 20A side is parallel to the optical axis of the light L output from the light emitting device 2.

On the optical axis of the light emitting device 2, for example, three lenses 3, 4, and 5 are arranged. The lens 3 parallelizes the laser light L output from the light emitting device 2. The lens 4 condenses the light parallelized by the lens 3, and guides the light to the incidence-side end face 20A. The lens 5 parallelizes the light amplified by the optical amplifying device 1, and output from the emission-side end face 20B. In addition, the lens 5 may be omitted depending on the intended use.

The lenses 4 and 5 are, for example, arranged in such a manner that the optical axis of the lenses 4 and 5 is directed in the direction intersecting the normal (optical axis AX1) of the emission-side end face 20B at the angle θ defined by the following equation.

sin θ=sin α×(n₁/n₂)

Here, α is an angle between the normal (optical axis AX1) of the emission-side end face 20B and a line parallel to the extending direction of the ridge 129. n₁ is the refractive index of a material constituting the optical path of the optical amplifying element 20. n₂ is the refractive index of a gas in contact with the surface of the lens 5 on the optical amplifying element 20 side.

(Structure of the Light Emitting Device 2)

For example, as illustrated in FIG. 6, the light emitting device 2 includes, for example, a stem 40, a light emitting element 50, and a cap 60.

The stem 40 constitutes the package of the light emitting device 2 in corporation with the cap 60, and includes, for example, a supporting substrate 41 supporting the light emitting element 50, and a plurality of connecting terminals 42. The plurality of connecting terminals 42 are electrically connected to the light emitting element 50 through the wiring (not illustrated in the figure) or the like. The light emitting element 50 converts the electrical signal into the optical signal to output the optical signal, and outputs, for example, the light in the direction parallel to the normal of the supporting substrate 41. The light emitting element 50 is, for example, an edge emitting semiconductor laser, and arranged in such a manner that the optical axis is parallel to the normal of the supporting substrate 41. Although not illustrated in the figure, the light emitting element 50 includes the front end face and the rear end face, and emits light from the front end face.

A wavelength λ2 of the light emitted from the light emitting element 50 is, for example, from 300 nm to 600 nm both inclusive, preferably from 360 nm to 550 nm both inclusive, and more preferably from 360 nm to 430 nm both inclusive. The wavelength λ2 has a value within a range of λ1±5 nm, and preferably has a value within a range of λ1±2 nm. Further, the wavelength λ2 is preferably longer than the wavelength λ1.

Like the optical amplifying element 20, the light emitting element 50 contains AlGaInN. Although not illustrated in the figure, for example, in the light emitting element 50, the stacked body including the AlGaInN active layer is formed on the GaN substrate. Although not illustrated in the figure, for example, each of the front end face and the rear end face is provided with the reflection coating film arranged on its surface. Here, when the current is injected into the light emitting element 50, and the light emission is generated in the active layer, the reflection coating film has a reflectance of such a degree that the light emitting element 50 is laser-oscillated by the emitted light repeatedly reflecting on the front end face and the rear end face. In this manner, by providing the reflection coating films on the front end face and the rear end face, the light emitting element 50 may perform the gain switching operation or the self pulsation operation. Although not illustrated in the figure, for example, the reflection coating film may be provided on the surface of the rear end face, and although not illustrated in the figure, for example, a film (non-reflection coating film) having the same function as the antireflection films 133 and 134 may be provided on the surface of the front end face. In this case, the external resonator is set by inserting a translucent mirror between the lens 3 and the lens 4, and therefore the light emitting element 50 may perform the mode-locked operation.

The cap 60 seals the light emitting element 50. The cap 60 includes, for example, a tube 61 in which an aperture is provided in each of the upper end and the lower end. The lower end of the tube 61 is fixed onto the top face of the supporting substrate 41, and the light emitting element 50 is positioned in the internal space of the tube 61. The cap 60 includes a light transmitting window 62 arranged so as to close the aperture 61A on the upper end side of the tube 61. As illustrated in FIG. 6, for example, the light transmitting window 62 is arranged in the light emission direction of the light emitting element 50, and has a function to transmit the light output from the light emitting element 50.

The optical amplifying device 1 of this embodiment may be manufactured, for example, as will be described next. First, after preparing the stem 10, the optical amplifying element 20, and the cap 30, the optical amplifying element 20 is mounted on the top face of the supporting substrate 11, and then the optical amplifying element 20 is sealed by the cap 30. Next, in dry air, the lower end (lower end of the tube 31) of the cap 30 and the top face 11A of the supporting substrate 11 are bonded to each other by electrical welding. In this manner, the optical amplifying device 1 of this embodiment is manufactured.

(Operation of the Optical Amplifying Device 1)

Next, with reference to FIG. 6, the operation of the optical amplifying device 1 will be described. First, when the electrical signal is input from the external to the light emitting element 50 in the light emitting device 2, the electrical signal is converted into the optical signal in the light emitting element 50, and the laser light L having the wavelength λ2 is output from the light emitting element 50 to the external through the light transmitting window 62. The laser light L output to the external is parallelized by the lens 3, condensed by the lens 4, and incident into the light transmitting window 32 of the optical amplifying device 1. After the light incident into the light transmitting window 32 transmits the light transmitting window 32, the light is incident into the incidence-side end face 20A of the optical amplifying element 20, is amplified by the optical amplifying element 20, and is output as the laser light having the wavelength λ1 to the external through the light transmitting window 32. The light output to the external is parallelized by the lens 5, and then incident into another device (not illustrated in the figure). In this manner, the laser light L output from the light emitting device 2 is amplified by the optical amplifying device 1.

Here, the optical amplifying element 20 is driven with a DC signal or a pulse signal. For example, a high-frequency signal having a pulse width of 20 ns, and a repetition frequency of 1 MHz is input as the pulse signal to the optical amplifying element 20. In the light emitting element 50, an optical pulse is output by the mode-locked operation, the gain switching operation, or the self pulsation operation, if necessary. This optical pulse is incident into the optical amplifying element 20, and thus the optical pulse having a high peak power is output from the optical amplifying element 20.

(Effects of the Optical Amplifying Device 1)

Next, the effects of the optical amplifying device 1 will be described. In this embodiment, the optical amplifying element 20 is sealed by the stem 10 and the cap 30, and the light transmitting window 32 is provided in each of the portion facing the incidence-side end face 20A and the portion facing the emission-side end face 20B in the cap 30. Therefore, it may be possible to seal the optical amplifying element 20 without inhibiting the light irradiation to the optical amplifying element 20, and the light emission from the optical amplifying element 20. As a result, a slight amount of a Si organic gas contained in an external atmosphere is suppressed from being reacted with the laser light to generate a deposited material on the incidence-side end face 20A and the emission-side end face 20B.

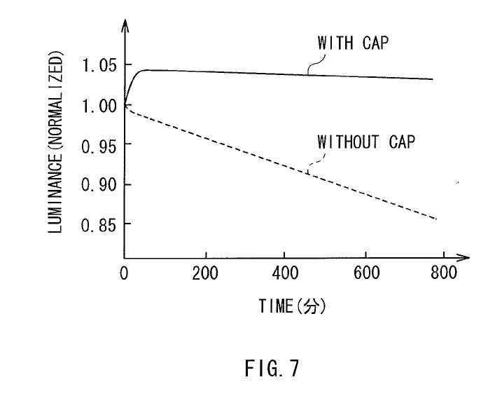

In particular, generation of the deposited material becomes an issue on the end faces like the incidence-side end face 20A and the emission-side end face 20B, where the antireflection films 133 and 134 are formed, and the reflectance is low. For example, in the case where the optical amplifying element 20 is exposed to the external atmosphere without providing the cap 30, the slight amount of the Si organic gas contained in the external atmosphere is reacted with the laser light. Therefore, the deposited material is generated on the incidence-side end face 20A and the emission-side end face 20B, and the reflectance on the incidence-side end face 20A and the emission-side end face 20B is changed due to the deposited material. Due to the change of the reflectance on the incidence-side end face 20A and the emission-side end face 20B, the drive current of the optical amplifying element 20 is changed, and the optical output is changed (reduced), for example, as illustrated with a broken line of FIG. 7.

Meanwhile, in this embodiment, the optical amplifying element 20 is sealed by the stem 10 and the cap 30, and generation of the deposited material on the incidence-side end face 20A and the emission-side end face 20B is suppressed. Therefore, it may be possible to suppress the change of the drive current of the optical amplifying element 20, and, further, it may be possible to suppress the change (reduction) of the optical output, as illustrated with the solid line of FIG. 7.

In this embodiment, in the case where the ridge 129 of the optical amplifying element 20 has the flare structure, and the width on the incidence-side end face 20A side is smaller than the width on the emission-side end face 20B side in the flare structure, it may be possible to output the laser light having the high output while maintaining the single-transverse mode at least in the width direction. Further, since the single-transverse mode is maintained at least in the width direction, it may be possible to realize high optical coupling efficiency between the optical amplifying element 20 and another optical system.

(Modification of the First Embodiment)

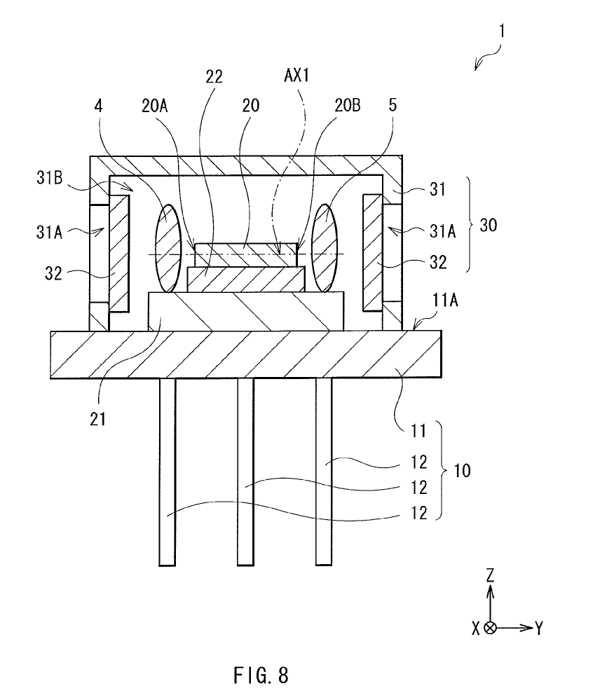

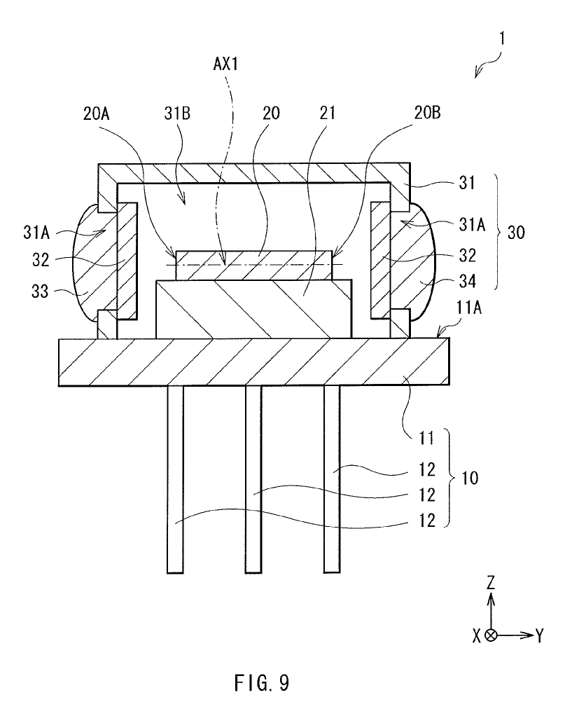

In the foregoing embodiment, although only the optical amplifying element 20 and the sub-mount 21 are provided in the internal space 31B of the tube 31, for example, as illustrated in FIG. 8, the lenses 4 and 5 may be provided. At this time, the lens 4 is provided between the incidence-side end face 20A and the light transmitting window 32, and the lens 5 is provided between the emission-side end face 20B and the light transmitting window 32. To align the optical axis AX1 of the optical amplifying element 20 and the optical axis of the lenses 4 and 5, a sub-mount 22 may be additionally provided between the optical amplifying element 20 and the sub-mount 21. For example, as illustrated in FIG. 9, in substitution for the lenses 4 and 5, lenses 33 and 34 having shapes which may be fitted into the apertures 31A of the tube 31 may be set in the apertures 31A. In this case, when the light transmitting windows 32 and the lenses 33 and 34 are conceptually combined, it can be said that a combination of the light transmitting window 32 and the lens 33 or 34 is a light transmitting window having a lens function. At this time, the lenses 33 and 34 may be bonded onto the light transmitting windows 32 with an adhesive (not illustrated in the figure). Therefore, it may be possible to reduce the number of steps necessary for positioning the lenses 4 and 5, in comparison with the case where the lenses 4 and 5 are provided separately from the optical amplifying device 1 as in the foregoing embodiment.

In the foregoing embodiment, although the optical amplifying element 20 is a so-called transmissive SOA, for example, the optical amplifying element 20 may be a so-called resonant SOA, although not illustrated in the figure. However, in this case, although not illustrated in the figure, the incidence-side end face 20A and the emission-side end face 20B include reflection coating films (first reflection coating films) on the surface, in substitution for the antireflection films 133 and 134. Here, when the light having a predetermined wavelength (from 300 nm to 600 nm both inclusive) is incident into the incidence-side end face 20A, and stimulated emission is generated in the active layer by the incident light, the reflection coating film has a reflectance of such a degree that the stimulated emission light is amplified by repeatedly reflecting on the incidence-side end face 20A and the emission-side end face 20B, and the laser light is output from both the incidence-side end face 20A and the emission-side end face 20B.

### 2. Second Embodiment

### Structure of a Light Emitting Device 6

FIG. 10 illustrates an example of the cross-sectional structure of a light emitting device 6 in the longitudinal direction, according to a second embodiment of the present invention. In addition, FIG. 10 is a schematic illustration, and the dimensions and the shapes are different from actual dimensions and actual shapes.

The structure of the light emitting device 6 of this embodiment is different from that of the optical amplifying device 1 of the foregoing embodiment in that a light emitting element 70 is provided in substitution for the optical amplifying element 20 of the light emitting device 1 of the foregoing embodiment. Thus, hereinafter, the difference from the foregoing embodiment will be mainly described, and description of the points common to those of the foregoing embodiment will be appropriately omitted.

The light emitting element 70 converts the electrical signal into the optical signal to output the optical signal, and outputs, for example, the light in the direction parallel to the top face 11A of the supporting substrate 11. The light emitting element 70 is, for example, the edge emitting semiconductor laser, and is arranged in such a manner that the optical axis is parallel to the top face 11A. The light emitting element 70 includes an emission-side end face 70A and a transmission-side end face 70B, and emits the light from the incidence-side end face. The center wavelength of the light (stimulated emission light) emitted from the light emitting element 70 is, for example, from 300 nm to 600 nm both inclusive, preferably from 360 nm to 550 nm both inclusive, and more preferably from 360 nm to 430 nm both inclusive. Like the optical amplifying element 20, the light emitting element 70 contains AlGaInN, and, in the light emitting element 70, for example, the stacked body including the AlGaInN active layer is formed on the GaN substrate, although not illustrated in the figure. Although not illustrated in the figure, for example, the transmission-side end face 70B includes the antireflection film (second reflection coating film) having the same function as the antireflection films 133 and 134 on the surface. Meanwhile, although not illustrated in the figure, the emission-side end face 70A includes the reflection coating film on the surface. Here, when the current is injected into the light emitting element 70, and the light emission is generated in the active layer, the reflection coating film has the reflectance of such a degree that the light emitting element 70 is laser-oscillated by the emitted light repeatedly reflecting on the emission-side end face 70A and a reflecting mirror 7 which will be described later, and the laser light is output from the emission-side end face 70A. In other words, here, the reflection coating film has the reflectance of such a degree that the external resonator is composed of the emission-side end face 70A and the reflecting mirror 7 which will be described later in the light having the predetermined wavelength. Here, for example, the predetermined wavelength is from 300 nm to 600 nm both inclusive, preferably from 360 nm to 550 nm both inclusive, and more preferably from 360 nm to 430 nm both inclusive.

For example, as illustrated in FIG. 11, the light emitting device 6 of this embodiment is used together with the reflecting mirror 7, and the lenses 8 and 9. The reflecting mirror 7 and the lens 8 are arranged in the space outside the light emitting device 6, and on the transmission-side end face 70B side. The reflecting mirror 7 and the lens 8 are arranged in the region facing the light transmitting window 32 on the transmission-side end face 70B side in the two light transmitting windows 32. The reflecting mirror 7 and the lens 8 are arranged on the optical axis (not illustrated in the figure) of the light emitting element 70, and the lens 8 is arranged closer on the light emitting device 6, in comparison with the reflecting mirror 7. Meanwhile, the lens 9 is arranged in the space outside the light emitting device 6, and on the emission-side end face 70A side. The lens 9 is arranged in the region facing the light transmitting window 32 on the emission-side end face 70A side in the two light transmitting windows 32. The lens 9 is also arranged on the optical axis (not illustrated in the figure) of the light emitting element 70.

Here, for example, the lens 8 parallelizes the laser light output from the transmission-side end face 70B of the light emitting device 6. It is enough for the lens 8 to adjust the emission angle of the incident light, and the lens 8 may not parallelize the incident light in a strict sense. The reflecting mirror 7 reflects the light parallelized by the lens 8 so that the light returns to the lens 8, and constitutes the external resonator in corporation with the emission-side end face 70A. The lens 9 parallelizes the laser light output from the emission-side end face 70A of the light emitting device 6. In addition, the lens 9 may be omitted depending on the intended use.

(Operation of the Light Emitting Device 6)

Next, with reference to FIG. 11, the operation of the light emitting device 6 will be described. First, when the electrical signal is input from the external to the light emitting element 70 in the light emitting device 6, the electrical signal is converted into the optical signal in the light emitting element 70, and the laser light is output from the transmission-side end face 70B of the light emitting element 70 to the external through the light transmitting window 32. After the laser light output to the external is parallelized by the lens 8, the laser light is reflected by the reflecting mirror 7, and returns to the light emitting element 70. The stimulated emission is generated in the active layer by the light which returns to the light emitting element 70. The light emitting element 70 is laser-oscillated by the stimulated emission light repeatedly reflecting on the emission-side end face 70A and the reflecting mirror 7, and the laser light is output from the emission-side end face 70A. In this manner, the laser oscillation is generated in the light emitting device 6.

(Effects of the Light Emitting Device 6)

Next, the effects of the light emitting device 6 will be described. In this embodiment, the light emitting element 70 is sealed by the stem 10 and the cap 30, and the light transmitting window 32 is provided in each of the portion facing the emission-side end face 70A and the portion facing the transmission-side end face 70B in the cap 30. Therefore, it may be possible to seal the light emitting element 70 without inhibiting the light incidence into the light emitting element 70, and the light emission from the light emitting element 70. As a result, the slight amount of the Si organic gas contained in the external atmosphere is suppressed from being reacted with the laser light to generate the deposited material on the emission-side end face 70A and the transmission-side end face 70B.

### 3. Examples

Next, examples 1 and 2 of the optical amplifying device 1 according to the first embodiment will be described. In the examples 1 and 2, in the optical amplifying device 1 according to the first embodiment, the device length was 3 mm, and the ridge 129 had the flare structure. In the example 1, as illustrated in FIG. 3A, for example, the ridge 129 was a straight type. In the example 2, as illustrated in FIG. 4, for example, the ridge 129 was an oblique waveguide type.

In both of the examples 1 and 2, CW light having the wavelength of 404 nm is input to the incidence-side end face 20A, and a spectrum of the light output at this time from the optical amplifying device 1 of the examples 1 and 2 was measured. The results of the example 1 at that time were indicated in FIG. 12A, and the results of the example 2 were indicated in FIG. 12B. Further, the magnitude of the drive current input to the optical amplifying device 1 of the example 1 was varied, and the output power at that time was measured. The results were indicated in FIG. 13.

From FIGS. 12A and 12B, it can be seen that the high-power longitudinal mode structure determined by the device length is notably displayed in the straight type optical amplifying device 1, but the longitudinal mode structure is hardly seen in the optical amplifying device 1 in which the waveguide is obliquely formed. This indicates that the depth of the longitudinal mode is reduced by obliquely forming the waveguide, and the residual reflection of the end face is suppressed.

From FIG. 13, the tendency that the output was saturated was seen when the input power was 300 mW or less, and the maximum output was approximately 200 mW when the input power was 12 W, and the drive current was 500 mA. Therefore, when it is desired to use the characteristic that the output power is linearly increased to the input power, the low current injecting region of the optical amplifying device 1 may be utilized, and when it is desired to stably utilize the higher output, the high current injecting region may be utilized.

The present application contains subject matter related to that disclosed in Japanese Priority Patent Application JP 2009-250624 filed in the Japan Patent Office on Oct. 30, 2009 and Japanese Priority Patent Application JP 2010-045394 filed in the Japan Patent Office on Mar. 2, 2010, the entire contents of which is hereby incorporated by references.

It should be understood by those skilled in the art that various modifications, combinations, sub-combinations and alternations may occur depending on design requirements and other factors insofar as they are within the scope of the appended claims or the equivalents thereof.

What is claimed is:

1. An optical device comprising:
an optical element including a first end face and a second end face, and emitting light having a wavelength from 300 nm to 600 nm both inclusive at least from the second end face in the first end face and the second end face;
a pedestal including a supporting substrate supporting the optical element, and a connecting terminal electrically connected to the optical element; and
a sealing section including a light transmitting window in each of a portion facing the first end face and a portion facing the second end face, and sealing the optical element.

2. The optical device according to claim 1, wherein each light transmitting window contains a transparent member in which an antireflection film is formed on a surface.

3. The optical device according to claim 1, wherein the optical element serves as an optical amplifying element amplifying the light incident into the first end face, and emitting the light having a luminance larger than that of the incident light at least from the second end face in the first end face and the second end face.

4. The optical device according to claim 3, wherein each of the first end face and the second end face has an antireflection film on the surface.

5. The optical device according to claim 3, wherein the optical element is directed toward the first end face in a direction that the first end face and the light transmitting window do not frontally face each other.

6. The optical device according to claim 3, wherein the optical element contains a wurtzite semiconductor crystal.

7. The optical device according to claim 3, wherein the optical element contains AlGaInN.

8. The optical device according to claim 3, further comprising:
a first lens between the light transmitting window and the first end face; and
a second lens between the light transmitting window and the second end face.

9. The optical device according to claim 3, wherein the transparent member has a lens function.

10. The optical device according to claim 3, wherein when the light having the wavelength from 300 nm to 600 nm both inclusive is incident into the first end face, and stimulated emission is generated by the incident light, each of the first end face and the second end face includes a first reflection coating film having a reflectance of a degree that the stimulated emission light is amplified, and laser light is output from each of the first end face and the second end face.

11. The optical device according to claim 3, wherein
the optical element includes a ridge having a flare structure, and
a width of the ridge on the first end face side is set to be smaller than the width of the ridge on the second end face side.

12. The optical device according to claim 1, wherein the optical element is configured as a semiconductor laser.

13. The optical device according to claim 11, further comprising a third lens in a region facing the light transmitting window on the second end face side in the two light transmitting windows, and a reflecting mirror in this order from the light transmitting window side, wherein
the second end face includes the antireflection film on the surface, and
the first end face includes a second reflection coating film having a reflectance of a degree that an external resonator is composed of the first end face and the reflecting mirror in the light having the wavelength from 300 nm to 600 nm both inclusive.
